(19) United States
(12) Patent Application Publication
(10) Pub. No.: US 2002/0135439 A1
(43) Pub. Date: Sep. 26, 2002

(54) Low-pass filter for use at user end or office end in communication network

(76) Inventors: Her-Jun Chueh, Taipei (TW); Kuang-Che Chen, Taipei (TW)

Correspondence Address: Michael Best & Friedrich LLC, 401 North Michigan Avenue, Chicago, IL, 60611, US

(21) Appl. No.: 09/902,249

(22) Filed: Jul. 10, 2001

(30) Foreign Application Priority Data
Mar. 22, 2001 (TW) 90106820

(51) Int. Cl. H03H 7/01

(52) U.S. Cl. 333/175; 333/172

(57) ABSTRACT

A low-pass filter for use at a user end or an office end in a communication network is disclosed. By providing a capacitive compensation circuit for the low-pass filter, the low-pass filter exhibits an improved attenuation value in a high-frequency band and a general attenuation value in a low-frequency band. The satisfactory attenuation performance in the high-frequency band minimizes the signal interference of a high-band communication terminal with a low-band communication terminal in the communication network. On the other hand, the maintained attenuation value in the low-frequency band allows the low-pass filter to comply with the stipulations of a communication system, e.g. the performance criteria stipulated by TIE1.4.

### FIELD OF THE INVENTION

The present invention relates to a low-pass filter, and more particularly to a low-pass filter for use at a user end or office end in a communication network.

### BACKGROUND OF THE INVENTION

In order to enhance the data transmission rate in the internet, various techniques for broadband linkage are developed. For example, Digital Subscriber Line (DSL) uses copper wires common to general users to perform high-speed data transmission. Nowadays, many different versions of DSL techniques have been derived, and they are generally known as xDSL. Among them, the most popular one, so far, is Asymmetric Digital Subscriber Line (ADSL).

Please refer to FIG. 1 which is a schematic diagram showing the application structure of ADSL. As shown, voice grade terminals 11 such as telephone sets or fax machines, and a remote terminal end 12 of an ADSL transceiver unit (ATU-R) share a conventional telephone line 10 to perform transmission therefor. The telephone line 10 is connected to a central office end 14 via a network interface device (NID) 13.

In general, ADSL utilizes a high frequency band, e.g. 25 kHz to 1 MHz, of the telephone line 10 to transmit information in the internet. Therefore, in principle, a low frequency band, e.g. a voice band, of the telephone line 10 can be provided for the voice grade terminals 11 to make a phone call or fax. In practice, however, the signal in the high frequency band may interfere with the signal in the low frequency band so as to adversely effect the telephone or facsimile communication quality relating to attenuation values. In order to solve this problem, low-pass filters 111 are provided between respective voice grade terminals 11 and the telephone line 10. The circuit of each low-pass filter 111 is optionally arranged inside or outside the housing of the corresponding voice grade terminal 11. FIG. 2 shows a circuit diagram of a conventional low-pass filter.

To minimize the influence on the entire communication network, e.g. causing malfunctions of telephone, Caller ID, and similar devices, the low-pass filter 111 is required to comply with various stipulations concerning each part of the communication network, e.g. as the performance criteria stipulated by T1E1.4. For example, to maximize performance of ADSL, the attenuation of the low-pass filter at 25 KHz should be at least 21 dB. Although the conventional low-pass filter as shown in FIG. 2 can achieve the required attenuation by increasing inductance (X_{L}) or capacitance (Xc), such modification will fail the stipulation for the voice band, i.e. 200 Hz to 4 kHz, and hence downgrade the voice communication quality.

### SUMMARY OF THE INVENTION

Therefore, an object of the present invention is to provide a low pass filter which complies with the requirements on the attenuation value as well as the stipulations concerning each parts of the communication structure e.g., the performance criteria stipulated by T1E1.4.

The present invention relates to a low-pass filter for use in a communication network. The communication network includes a high-band communication terminal, a low-band communication terminal, and a signal channel common to the high-band and low-band communication terminals. For example, the communication network may include an ATU-R as the high-band communication terminal, a voice grade terminal as the low-band communication terminal, and a telephone line as a signal channel. For another example, the communication network includes a home PNA client as the high-band communication terminal, a voice grade terminal as the low-band communication terminal, and a telephone line as a signal channel.

According to a first aspect of the present invention, the low-pass filter includes a first input end and a second input end for electrically connecting to the signal channel; a first output end and a second output end for electrically connecting to the low-band communication terminal; a first capacitor having a first and a second ends thereof connected to the first and second output ends, respectively; a first inductor connected to the first input end and first output end in series; a first compensation circuit connected to the first inductor in parallel, and including a first portion and a second portion interconnected in series, the first portion consisting of a first compensation capacitor and a first compensation resistor interconnected in parallel, and the second portion consisting of a second compensation capacitor and a second compensation resistor interconnected in series; a second inductor having an impedance equal to that of the first inductor, and connected between the second input end and second output end in series; and a second compensation circuit having an equivalent impedance equal to that of the first compensation circuit, connected to the second inductor in parallel, and including a third portion and a fourth portion, the third portion consisting of a third compensation capacitor and a third compensation resistor interconnected in parallel, and the fourth portion consisting of a fourth compensation capacitor and a fourth compensation resistor interconnected in series.

According to a second aspect of the present invention, the low-pass filter includes a first input end and a second input end for electrically connecting to the signal channel; a first output end and a second output end for electrically connecting to the low-band communication terminal; a first capacitor having a first and a second ends thereof connected to the first and second output ends, respectively; a first inductor connected to the first input end and first output end in series; a first compensation circuit connected to the first inductor in parallel, and including a first compensation capacitor and a first compensation resistor interconnected in series; a second inductor having an impedance equal to that of the first inductor, and connected between the second input end and second output end in series; and a second compensation circuit having an equivalent impedance equal to that of the first compensation circuit, connected to the second inductor in parallel, and including a second compensation capacitor and a second compensation resistor interconnected in series.

According to a third aspect of the present invention, the low-pass filter includes a first input end and a second input end for electrically connecting to the signal channel; a first output end and a second output end for electrically connecting to the low-band communication terminal; a first capacitor having a first and a second ends thereof connected to the first and second output ends, respectively; a first inductor connected to the first input end and first output end in series; a first capacitive compensation circuit connected to the first inductor in parallel, and including a first compensation capacitor; a second inductor having an impedance equal to that of the first inductor, and connected between the second input end and second output end in series; and a second capacitive compensation circuit having an impedance equal to that of the first capacitive compensation circuit, connected to the second inductor in parallel, and including a second compensation capacitor.

The term “capacitive compensation circuit” used herein indicates circuitry utilizing the property of a capacitor to achieve a compensation effect.

### BRIEF DESCRIPTION OF THE DRAWINGS

The present invention may best be understood through the following description with reference to the accompanying drawings, in which:

FIG. 1 is a schematic block diagram showing the application structure of ADSL;

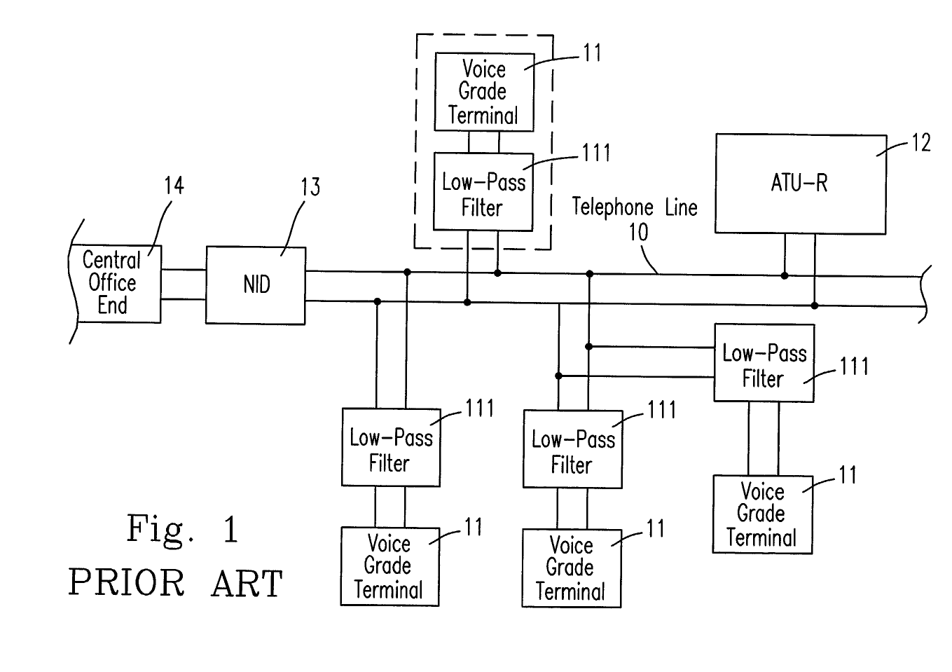

FIG. 2 is a circuit diagram of a conventional low-pass filter;

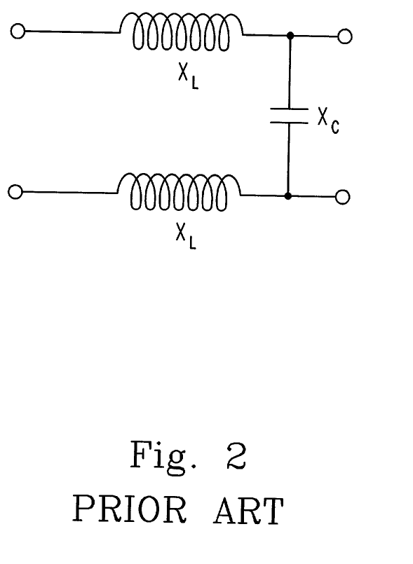

FIG. 3 is a circuit diagram of a first embodiment of a low-pass filter according to the present invention; and

FIG. 4 is a circuit diagram of a second embodiment of a low-pass filter according to the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only; it is not intended to be exhaustive or to be limited to the precise form disclosed.

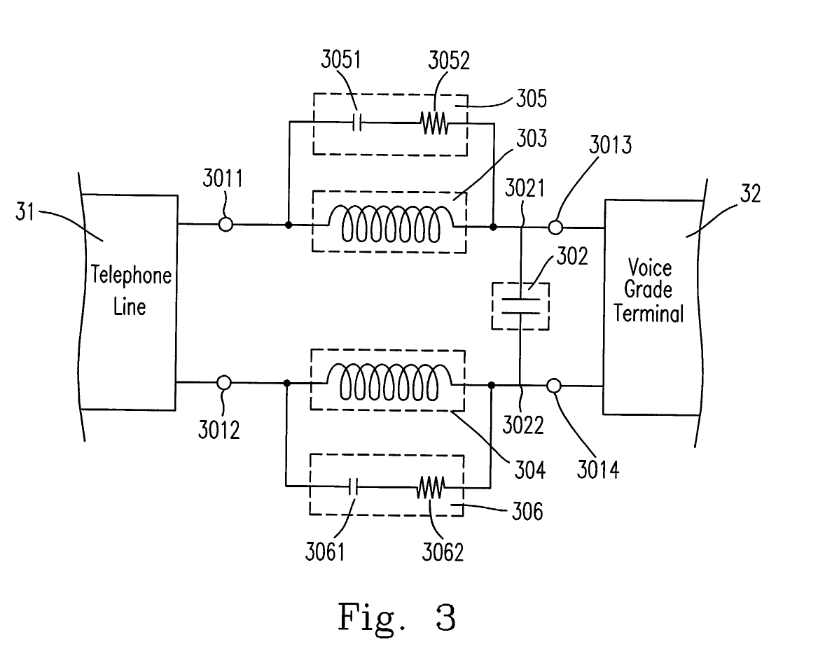

Please refer to FIG. 3 which is a circuit diagram of a first embodiment of a low-pass filter according to the present invention. As shown, the low-pass filter includes a number of pins. Two input pins 3011 and 3012 are electrically connected to a telephone line 31, and two output pins 3013 and 3014 are electrically connected to a voice grade terminal 32. A capacitor 302 has two ends 3021 and 3022 thereof connected to the output pins 3013 and 3014, respectively. An inductor 303 is serially connected between the input pin 3011 and the output pin 3013, and another inductor 304 is serially connected between the input pin 3012 and the output pin 3014. The impedance of the second inductor is equal to that of the first inductor.

In order to enhance the attenuation performance of the low-pass filter in the high-frequency band without significantly influencing the attenuation value in the low-frequency band, two capacitive circuits 305 and 306 are provided for compensation. The compensation circuit 305 is connected to the inductor 303 in parallel, and includes a compensation capacitor 3051 and a compensation resistor 3052. The compensation capacitor 3051 and the compensation resistor 3052 are connected to each other in series. Similarly, the compensation circuit 306 is connected to the inductor 304 in parallel, and having equivalent impedance equal to that of the compensation circuit 305. The compensation circuit 306 includes a compensation capacitor 3061 and a compensation resistor 3062. The compensation capacitor 3061 and the compensation resistor 3062 are connected to each other in series.

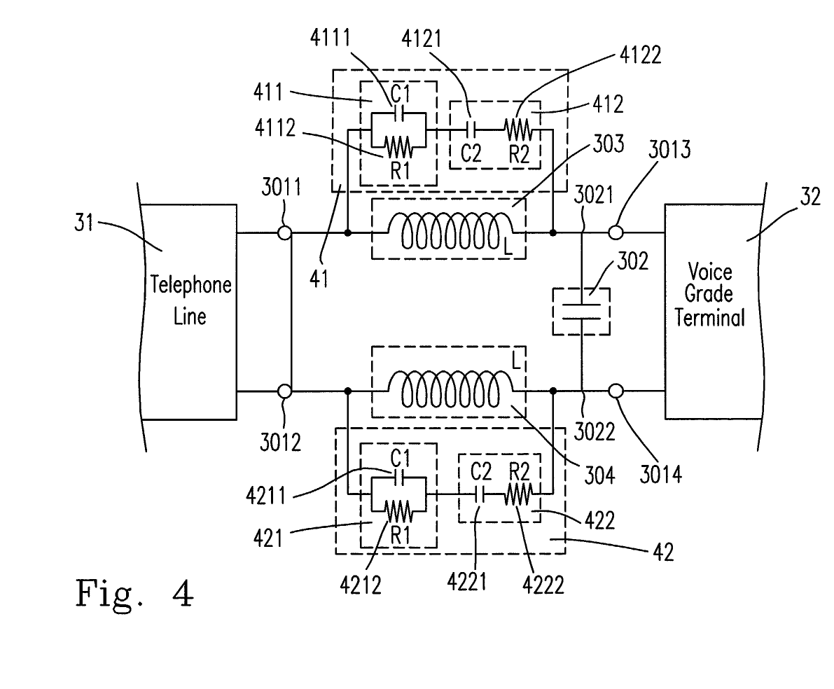

Please refer to FIG. 4 which is a circuit diagram of a second embodiment of a low-pass filter according to the present invention. Similar to the circuitry of FIG. 3, the low-pass filter includes two input pins 3011 and 3012 electrically connected to a telephone line 31, and two output pins 3013 and 3014 electrically connected to a voice grade terminal 32. A capacitor 302 has two ends 3021 and 3022 thereof connected to the output pins 3013 and 3014, respectively. An inductor 303 is serially connected between the input pin 3011 and the output pin 3013, and another inductor 304 is serially connected between the input pin 3012 and the output pin 3014. The impedance of the second inductor is equal to that of the first inductor. On the other hand, the compensation effect is further improved by modifying the compensation circuits as follows.

One of the compensation circuits 41 of this embodiment of low-pass filter includes a first portion 411 and a second portion 412 connected with each other in series. The first portion 411 consists of a compensation capacitor 4111 and a compensation resistor 4112 connected with each other in parallel. The second portion 412 consists of a compensation capacitor 4121 and a compensation resistor 4122 connected with each other in series. Likewise, the other of the compensation circuits 42 of this embodiment of low-pass filter includes a third portion 421 and a fourth portion 422 connected with each other in series. The third portion 421 consists of a compensation capacitor 4211 and a compensation resistor 4212 connected with each other in parallel. The fourth portion 422 consists of a compensation capacitor 4221 and a compensation resistor 4222 connected with each other in series. The equivalent impedance of the first compensation circuit is also equal to that of the second compensation circuit.

Hereinafter, an example is given to further describe the function of the low-pass filter according to the present invention with reference to FIG. 4. It is given that a resistance R1 of each of the compensation resistors 4112 and 4212 is 1 kΩ, a capacitance C1 of each of the compensation capacitors 4111 and 4211 is 220 pf, a resistance R2 of each of the compensation resistors 4122 and 4222 is 1.5 kΩ, a capacitance C2 of each of the compensation capacitors 4121 and 4221 is 1500 pf, and an inductance of each of the inductors 303 and 304 is 8 mH. As known, the impedance Z_{T}′ of each of the first and third compensation circuit portions 411 and 421 is equivalent to R₁//Z_{cl}, in which Z_{cl}=R_{xc1}+(1/jωC₁), ω=2πf, and f is an operational frequency. The impedance Z_{T}″ of each of the second and fourth compensation circuit portions 412 and 422 is equivalent to R₂//Z_{c2}, in which Z_{c2}=R_{xc2}+(1/jωC₂) and ω=2πf The impedance Z_{L} of each of the inductors 303 and 304 is equivalent to R_{L}+jωL), in which ω=2πf. Moreover, the equivalent impedance Z_{T} of the entire circuit consisting of the inductor 303 and compensation circuit 41 in parallel connection, and the inductor 304 and compensation circuit 42 in parallel connection is equivalent to Z_{L}//(Z_{T}′+Z_{T}″). Now, the impedance Z_{L} of the inductor 303 or 304 is compared with the impedance Z_{T}=Z_{L}//(Z_{T}′+Z_{T}″) in order to illustrate the advantage of the present low-pass filter.

For an operational frequency of 4 kHz, the equivalent impedance Z_{L} of the inductor 303 or 304 is 219.7Ω (7.9Ω for a real part and 219.6Ω for an imaginary part). On the other hand, the equivalent impedance Z_{T} of the entire circuit incorporating therein the compensation circuit 41 or 42 is 221.6Ω (8.4Ω for a real part and 221.5Ω for an imaginary part), which approximates to the equivalent impedance Z_{L} of the inductor. Accordingly, the low-pass filter according to the present invention can maintain the attenuation performance as required within a low-frequency band.

On the other hand, for an operational frequency of 25 kHz, while the equivalent impedance Z_{L} of the inductor 303 or 304 is 1.4 kΩ (11Ω for a real part and 1.4 kΩ for an imaginary part), the equivalent impedance Z_{T} of the entire circuit incorporating therein the compensation circuit 41 or 42 is 2.014 kΩ (905Ω for a real part and 1.8 kΩ for an imaginary part). As understood, the equivalent impedance Z_{T} is much larger than the equivalent impedance Z_{L}. Accordingly, the attenuation value of the low-pass filter can be efficiently increased within a high frequency band.

As shown from the above example, the low-pass filter according to the present invention exhibits an improved attenuation value in a high-frequency band and a general attenuation value in a low-frequency band, thereby minimizing signal interference of a communication system as well as following the stipulations of the communication system, e.g. the performance criteria stipulated by TIE1.4. Therefore, the low-pass filter according to the present invention is suitable to be used at a user end or an office end of a communication network such as xDSL, G. Lite, or Home PNA. Further, in order to result in an even better compensation effect, an additional inductor of a low inductance can be serially connected to the capacitive compensation circuit. The principle is understood by those skilled in the art by referring to the above description, so it is not to be redundantly described herein.

While the invention has been described in terms of what are presently considered to be the most practical and preferred embodiments, it is to be understood that the invention need not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A low-pass filter for use in a communication network, said communication network including a high-band communication terminal, a low-band communication terminal, and a signal channel common to said high-band and low-band communication terminals, said low-pass filter comprising:
a first input end and a second input end for electrically connecting to said signal channel;
a first output end and a second output end for electrically connecting to said low-band communication terminal;
a first capacitor having a first and a second ends thereof connected to said first and second output ends, respectively;
a first inductor connected to said first input end and first output end in series;
a first compensation circuit connected to said first inductor in parallel, and including a first portion and a second portion interconnected in series, said first portion consisting of a first compensation capacitor and a first compensation resistor interconnected in parallel, and said second portion consisting of a second compensation capacitor and a second compensation resistor interconnected in series;
a second inductor having an impedance equal to that of said first inductor, and connected between said second input end and second output end in series; and
a second compensation circuit having an equivalent impedance equal to that of said first compensation circuit, connected to said second inductor in parallel, and including a third portion and a fourth portion, said third portion consisting of a third compensation capacitor and a third compensation resistor interconnected in parallel, and said fourth portion consisting of a fourth compensation capacitor and a fourth compensation resistor interconnected in series.

2. The low-pass filter according to claim 1 for use in a communication network including an ATU-R as said high-band communication terminal, a voice grade terminal as said low-band communication terminal, and a telephone line as a signal channel.

3. The low-pass filter according to claim 1 for use in a communication network including a home PNA client as said high-band communication terminal, a voice grade terminal as said low-band communication terminal, and a telephone line as a signal channel.

4. The low-pass filter according to claim 1 wherein a resistance of each of said first and third compensation resistors is 1 kΩ, a capacitance of each of said first and third compensation capacitors is 220 pf, a resistance of each of said second and fourth compensation resistors is 1.5 kΩ, a capacitance of each of said second and fourth compensation capacitors is 1500 pf, and an inductance of each of said first and second inductors is 8 mH.

5. A low-pass filter for use in a communication network, said communication network including a high-band communication terminal, a low-band communication terminal, and a signal channel common to said high-band and low-band communication terminals, said low-pass filter comprising:
a first input end and a second input end for electrically connecting to said signal channel;
a first output end and a second output end for electrically connecting to said low-band communication terminal;
a first capacitor having a first and a second ends thereof connected to said first and second output ends, respectively;
a first inductor connected to said first input end and first output end in series;
a first compensation circuit connected to said first inductor in parallel, and including a first compensation capacitor and a first compensation resistor interconnected in series;
a second inductor having an impedance equal to that of said first inductor, and connected between said second input end and second output end in series; and
a second compensation circuit having an equivalent impedance equal to that of said first compensation circuit, connected to said second inductor in parallel, and including a second compensation capacitor and a second compensation resistor interconnected in series.

6. The low-pass filter according to claim 5 for use in a communication network including an ATU-R as said high-band communication terminal, a voice grade terminal as said low-band communication terminal, and a telephone line as a signal channel.

7. The low-pass filter according to claim 5 for use in a communication network including a home PNA client as said high-band communication terminal, a voice grade terminal as said low-band communication terminal, and a telephone line as a signal channel.

8. A low-pass filter for use in a communication network, said communication network including a high-band communication terminal, a low-band communication terminal, and a signal channel common to said high-band and low-band communication terminals, said low-pass filter comprising:
a first input end and a second input end for electrically connecting to said signal channel;
a first output end and a second output end for electrically connecting to said low-band communication terminal;
a first capacitor having a first and a second ends thereof connected to said first and second output ends, respectively;
a first inductor connected to said first input end and first output end in series;
a first capacitive compensation circuit connected to said first inductor in parallel, and including a first compensation capacitor;
a second inductor having an impedance equal to that of said first inductor, and connected between said second input end and second output end in series; and
a second capacitive compensation circuit having an impedance equal to that of said first capacitive compensation circuit, connected to said second inductor in parallel, and including a second compensation capacitor.

9. The low-pass filter according to claim 5 for use in a communication network including an ATU-R as said high-band communication terminal, a voice grade terminal as said low-band communication terminal, and a telephone line as a signal channel.

10. The low-pass filter according to claim 5 for use in a communication network including a home PNA client as said high-band communication terminal, a voice grade terminal as said low-band communication terminal, and a telephone line as a signal channel.
